(19) United States
(12) Patent Application Publication
(10) Pub. No.: US 2007/0269974 A1
(43) Pub. Date: Nov. 22, 2007

(54) METHODS FOR FORMING A METAL CONTACT IN A SEMICONDUCTOR DEVICE IN WHICH AN OHMIC LAYER IS FORMED WHILE FORMING A BARRIER METAL LAYER

(76) Inventors: Hee-sook Park, Seoul (KR); Gil-heyun Choi, Yongin-city (KR); Sang-bum Kang, Seoul (KR); Seong-geon Park, Yongin-City (KR); Kwang-jin Moon, Yongin-city (KR)

Correspondence Address: MYERS BIGEL SIBLEY & SAJOVEC, PO BOX 37428, RALEIGH, NC, 27627, US

(21) Appl. No.: 11/754,639

(22) Filed: May 29, 2007

Related U.S. Application Data
(63) Continuation-in-part of application No. 11/112,356, filed on Apr. 22, 2005, now Pat. No. 7,223,689.
Application No. 11/112,356 is a division of application No. 10/615,362, filed on Jul. 8, 2003, now abandoned.
(63) Continuation-in-part of application No. 11/787,468, filed on Apr. 17, 2007.
Application No. 11/787,468 is a division of application No. 11/112,356, filed on Apr. 22, 2005, now Pat. No. 7,223,689.
Application No. 11/112,356 is a division of application No. 10/615,362, filed on Jul. 8, 2003, now abandoned.

(30) Foreign Application Priority Data
Aug. 23, 2002 (KR) 2002-50072

(51) Int. Cl. H01L 21/4763

(52) U.S. Cl. 438/618; 257/E21.495

(57) ABSTRACT

A metal contact in a semiconductor device is formed by forming an insulating layer having a contact hole therein on a silicon layer. A cobalt layer is formed on a bottom and inner walls of the contact hole. A cobalt silicide layer is formed at the bottom of the contact hole while forming a titanium layer on the cobalt layer. A plug is formed on the titanium layer so as to fill the contact hole.

### RELATED APPLICATIONS

This application is a continuation-in-part of U.S. application Ser. No. 11/112,356, filed Apr. 22, 2005, which is a divisional application of U.S. application Ser. No. 10/615,362, filed Jul. 8, 2003, which claims the benefit of and priority to Korean Patent Application No. 2002-50072, filed Aug. 23, 2002. This application also is a continuation-in-part of U.S. application Ser. No. 11/787,468, filed Apr. 17, 2007, which is a divisional application of U.S. application Ser. No. 11/112,356, filed Apr. 22, 2005, which is a divisional application of U.S. application Ser. No. 10/615,362, filed Jul. 8, 2003, which claims the benefit of and priority to Korean Patent Application No. 2002-50072, filed Aug. 23, 2002. The disclosures of the above-referenced patent applications are hereby incorporated herein by reference.

### FIELD OF THE INVENTION

The present invention relates to methods of manufacturing semiconductor devices, and, more particularly, to methods of forming metal contacts in semiconductor devices.

### BACKGROUND OF THE INVENTION

As semiconductor devices have become more highly integrated, the design rules for semiconductor devices have been gradually reduced. Accordingly, the areas associated with a contact, which connects individual devices to circuit interconnect wiring in the semiconductor device, and a via contact, which connects an upper interconnect wiring to a lower interconnect wiring, have generally been reduced. In addition, contact depth is generally increasing due to a multi-layered semiconductor device structure.

Consequently, because the resistance of contacts is generally increasing, which may degrade semiconductor device characteristics, technology for reducing contact resistance may be desirable. With contact surface area decreasing and depth increasing, achieving adequate step coverage may be difficult. In other words, the depth of the contact is increased while reducing the area of the contact to increase an aspect ratio so that a process of filling metal in a contact hole without a void or disconnection may be difficult.

FIGS. 1A and 1B are sectional views illustrating a conventional method for forming a metal contact in a semiconductor device. Referring to FIG. 1A, an insulating layer 15 having a contact hole 13 is formed on a silicon substrate 11. A titanium layer 17 and a titanium nitride layer 19 are sequentially formed in the contact hole 13 and on the insulating layer 15 to form a barrier metal layer 21. The titanium layer 17 operates as an ohmic layer and the titanium nitride layer 19 operates as a diffusion barrier layer for preventing the diffusion of a tungsten layer 25 (refer to FIG. 1B), which will be formed in a subsequent process, into the silicon substrate 11. The titanium nitride layer 19 may also improve the surface adhesion of the tungsten, which will be formed in a subsequent process. A thermal process, such as a rapid thermal processing (RTP) or a rapid thermal annealing (RTA), is performed on the silicon substrate 11 having the barrier metal layer 21 so that a titanium silicide 23 layer is formed.

Referring to FIG. 1B, a tungsten layer 25 is formed on the barrier metal layer 21 in order to fill the contact hole 13. The tungsten layer 25 may be formed by chemical vapor deposition (CVD), which has generally effective gap filling characteristics. Because the tungsten layer 25 is formed using CVD, the contact hole 13 is generally efficiently filled with the tungsten layer 25.

Because the titanium silicide 23 layer of FIGS. 1A and 1B has a relatively high level of contact resistance in a highly integrated semiconductor device, however, another material may be substituted for the titanium silicide layer 23. Accordingly, a method for forming a metal contact in a semiconductor device using cobalt silicide will now be discussed.

FIGS. 2A through 2F are sectional views illustrating a conventional method for forming a metal contact in a semiconductor device using cobalt silicide. Referring to FIG. 2A, an insulating layer 33 having a contact hole 32 is formed on a silicon substrate 31. A cobalt layer 35 is formed in the contact hole 32 and on the insulating layer 33 by physical vapor deposition (PVD). In addition, a titanium nitride layer 37 is formed on the cobalt layer 35.

Referring now to FIG. 2B, a first thermal process, such as RTP or RTA, is performed on the silicon substrate 31 on which the cobalt layer 35 and the titanium nitride layer 37 are formed to silicidate the silicon substrate 31 and to form a CoSiₓ layer 39 on the bottom of the contact hole 32.

Referring now to FIG. 2C, the silicon substrate 31, on which the CoSiₓ layer 39 is formed, is dipped in a sulfuric acid solution to strip the cobalt layer 35 and the titanium nitride layer 37 from the contact hole 32 and the insulating layer 33. As a result, the CoSiₓ layer 39 remains on the bottom of the contact hole 32. Because the CoSiₓ layer 39 has a relatively high resistance, the CoSiₓ layer 39 may be transformed into a CoSi₂ type cobalt silicide layer by performing a subsequent thermal process.

Referring now to FIG. 2D, a second thermal process, such as RTP or RTA, is performed on the silicon substrate 31 on which the CoSiₓ layer 39 is formed to silicidate the silicon substrate 31 and to form a cobalt silicide layer 41 on the bottom of the contact hole 32. Thereafter, the silicon substrate 31 having the cobalt silicide Layer 41 formed thereon is cleaned. Referring now to FIG. 2E, a titanium layer 43 and a titanium nitride layer 45 are sequentially formed on the top surface of the silicon substrate 31 having the cobalt silicide layer 41 to form a barrier metal layer 47.

Referring now to FIG. 2F, a tungsten layer 49 for filling the contact hole 32 is formed on the barrier metal layer 47. The tungsten layer 49 is formed using CVD, which has generally effective gap filling characteristics. Because the tungsten layer 49 is formed using CVD, the contact hole 32 is generally efficiently filled with the tungsten layer 49.

According to the method described with respect to FIGS. 2A through 2F, because the cobalt silicide layer 41 has a generally lower reactivity to dopant than titanium silicide, the cobalt silicide layer 41 can attain a lower contact resistance. Unfortunately, forming a metal contact in accordance with the method of FIGS. 2A through 2F involves performing thermal processes twice and a strip process. In addition, the cobalt layer 35 is formed using PVD according to the method described with respect to FIGS. 2A through 2F, which generally provides poorer step coverage. Accordingly, the thickness of the cobalt layer 35 is typically increased to obtain a cobalt silicide layer 41 having a proper thickness on the contact bottom. When such a thick cobalt layer 35 is deposited, a strip process for removing the cobalt layer 35, which remains after a silicidation process, may be necessary. Furthermore, a reinforced cleaning process is typically performed after the strip processes.

### SUMMARY OF THE INVENTION

According to some embodiments of the present invention, a metal contact in a semiconductor device is formed by forming an insulating layer having a contact hole therein on a silicon layer. A cobalt layer is formed on a bottom and inner walls of the contact hole. A cobalt silicide layer is formed at the bottom of the contact hole while forming a titanium layer on the cobalt layer. A plug is formed on the titanium layer so as to fill the contact hole.

In other embodiments, the plug comprises titanium nitride.

In still other embodiments, a titanium nitride layer is formed on the titanium layer and the plug is formed on the titanium nitride layer so as to fill the contact hole.

In still other embodiments, the titanium nitride layer has a thickness of about 50 to 500 A and is formed using chemical vapor deposition (CVD) at a temperature of about 400 to 750° C.

In still other embodiments, the plug comprises at least one of tungsten, titanium nitride, aluminum, and tantalum nitride.

In still other embodiments, the cobalt layer, the titanium layer, and the titanium nitride layer are formed in situ without a vacuum break.

In still other embodiments, the cobalt layer has a thickness of about 5 to 200 Å and is formed using one of physical vapor deposition (PVD) and chemical vapor deposition (CVD).

In still other embodiments, the cobalt layer is formed using PVD at a temperature of about 25 to 500° C.

In still other embodiments, the titanium layer has a thickness of about 5 to 150 Å and is formed using chemical vapor deposition (CVD) at a temperature of about 400 to 750° C.

In still other embodiments, the substrate and insulating layer are cleaned after forming the insulating layer.

In still further embodiments of the present invention, a metal contact in a semiconductor device is formed by forming an insulating layer having a contact hole therein on a silicon layer. A titanium layer is formed on a bottom and inner walls of the contact hole. A cobalt layer is formed on the titanium layer. A complex silicide layer comprises titanium silicide and cobalt silicide, which is formed at the bottom of the contact hole while forming a titanium nitride layer on the cobalt layer. A plug is formed on the titanium nitride layer so as to fill the contact hole.

In still further embodiments of the present invention, a metal contact in a semiconductor device is formed by forming an insulating layer having a contact hole therein on a silicon layer. A titanium layer is formed on a bottom and inner walls of the contact hole. A cobalt layer is formed on the titanium layer. A complex silicide layer comprising titanium silicide and cobalt silicide is formed at the bottom of the contact hole while forming a plug that fills the contact hole on the cobalt layer.

### BRIEF DESCRIPTION OF THE DRAWINGS

Other features of the present invention will be more readily understood from the following detailed description of specific embodiments thereof when read in conjunction with the accompanying drawings, in which:

FIGS. 1A and 1B are sectional views illustrating a conventional method for forming a metal contact in a semiconductor device;

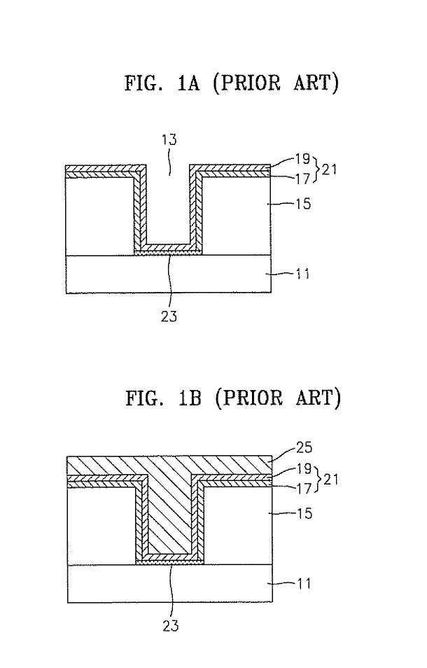

FIGS. 2A through 2F are sectional views illustrating a conventional method for forming a metal contact in a semiconductor device using cobalt silicide;

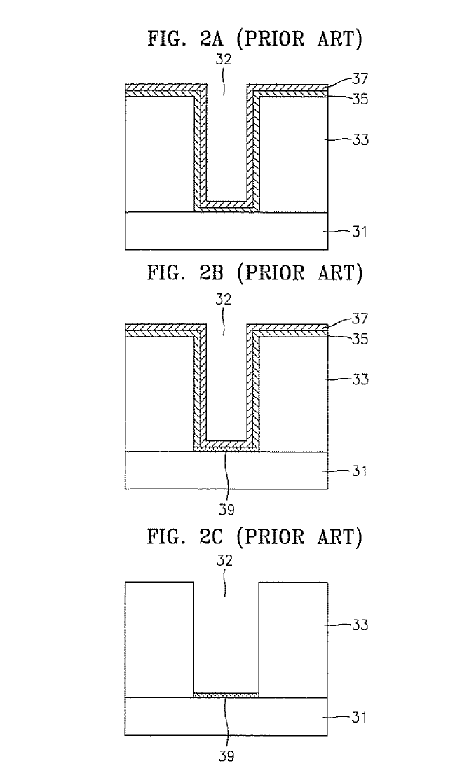

FIGS. 3A through 3D are sectional views that illustrate methods for forming a metal contact in a semiconductor device according to some embodiments of the present invention;

FIG. 4 is a sectional view that illustrates methods for forming a metal contact in a semiconductor device according to additional embodiments of the present invention;

FIGS. 5A through 5C are sectional views that illustrate methods for forming a metal contact in a semiconductor device according to additional embodiments of the present invention;

FIG. 6 is a sectional view that illustrates methods for forming a metal contact in a semiconductor device according to additional embodiments of the present invention;

FIGS. 7A through 7D are sectional views that illustrate methods for forming a metal contact in a semiconductor device according to additional embodiments of the present invention;

FIG. 8 is a sectional view that illustrates methods for forming a metal contact in a semiconductor device according to additional embodiments of the present invention;

FIG. 9 is a schematic view illustrating manufacturing equipment used for forming a metal contact in a semiconductor device according to some embodiments of the present invention;

FIG. 10 is a graph that illustrates contact resistances when metal contacts are formed in semiconductor devices according to conventional methods and methods according to various embodiments of the present invention;

FIGS. 11A and 11B are graphs illustrating contact resistances of N⁺ contacts and P⁺ contacts versus contact size when a bit line contact is formed in prior art semiconductor devices and semiconductor devices according to embodiments of the present invention;

FIGS. 12 and 13 are cross-sectional views illustrating a cell array region and a peripheral circuit region of a DRAM device, respectively, manufactured using a method according to some embodiments of the present invention;

FIGS. 14 and 15 are cross-sectional views illustrating a cell array region of a flash memory device manufactured using a method according some embodiments of the present invention;

FIGS. 16 and 17 are cross-sectional views illustrating a peripheral circuit region of a flash memory device manufactured using a method according to some embodiments of the present invention;

FIG. 18 is a cross-sectional view illustrating a PRAM device manufactured using a method according to some embodiments of the present invention; and

FIG. 19 is a cross-sectional view illustrating a PRAM device manufactured using a method according to further embodiments of the present invention.

### DETAILED DESCRIPTION

The invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout the description of the figures.

It will be understood that when an element is referred to as being “on” another element, it can be directly on the other element or intervening elements may be present. In contrast, when an element is referred to as being “directly on” another element, there are no intervening elements present. It will be understood that when an element is referred to as being “connected” or “coupled” to another element, it can be directly connected or coupled to the other element or intervening elements may be present. In contrast, when an element is referred to as being “directly connected or coupled” to another element, there are no intervening elements present. Furthermore, “connected” or “coupled” as used herein may include wirelessly connected or coupled. As used herein, the term “and/or” includes any and all combinations of one or more of the associated listed items.

It will be understood that, although the terms first, second, etc. may be used herein to describe various elements, these elements should not be limited by these terms. These terms are only used to distinguish one element from another. For example, a first layer could be termed a second layer, and, similarly, a second layer could be termed a first layer without departing from the teachings of the disclosure.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to other elements as illustrated in the Figures. It will be understood that relative terms are intended to encompass different orientations of the device in addition to the orientation depicted in the Figures. For example, if the device in one of the figures were turned over, elements described as being on the “lower” side of other elements would then be oriented on “upper” sides of the other elements. The exemplary term “lower”, can therefore, encompass both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments of the present invention are described herein with reference to cross section illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present invention.

In the description, a term “substrate” used herein may include a structure based on a semiconductor, having a semiconductor surface exposed. It should be understood that such a structure may contain silicon, silicon on insulator, silicon on sapphire, doped or undoped silicon, epitaxial layer supported by a semiconductor substrate, or another structure of a semiconductor. And, the semiconductor may be silicon-germanium, germanium, or germanium arsenide, not limited to silicon. In addition, the substrate described hereinafter may be one in which regions, conductive layers, insulation layers, their patterns, and/or junctions are formed.

For purposes of illustration, various embodiments of the present invention are described herein in which a cobalt silicide layer (or a complex silicide layer) is formed on a silicon substrate. It will be understood, however, that in a semiconductor device, the cobalt silicide layer (or the complex silicide layer) may be formed on a silicon layer including a silicon source in addition to the silicon substrate. For example, in a semiconductor device, the cobalt silicide layer (or the complex silicide layer) may be formed on a single crystal silicon layer, a poly crystal silicon layer and/or a silicide layer. The silicon layer formed on the semiconductor device may or may not be doped with impurities.

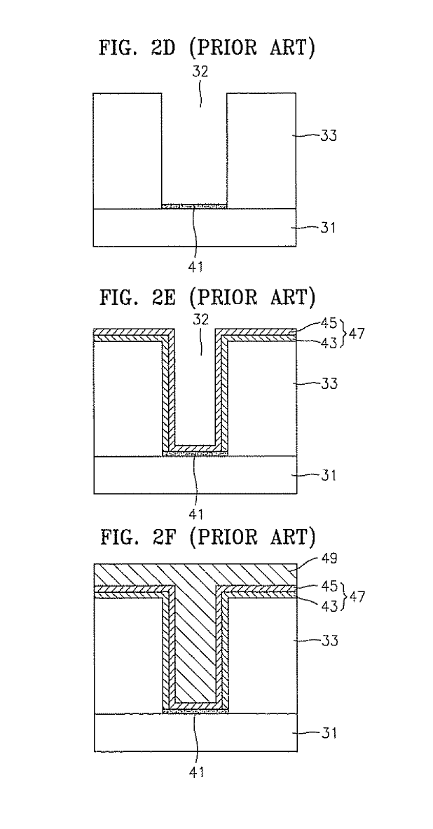

FIGS. 3A through 3D are sectional views that illustrate methods for forming a metal contact in a semiconductor device according to some embodiments of the present invention. Referring now to FIG. 3A, an insulating layer 105 having a contact hole 103 therein is formed on a silicon substrate 101. A cobalt layer 107, which may function as an ohmic layer, is formed on the inner walls and the bottom of the contact hole 103 and on the insulating layer 105. The cobalt layer 107 may be formed to a thickness of about 5 to 200 Å. The cobalt layer 107 may be formed using PVD or CVD (hereafter, CVD is referred to as including an atomic layer deposition (ALD) method). When the cobalt layer 107 is formed using PVD, the cobalt layer 107 is deposited at a temperature of about 25 to 500° C. In particular embodiments, the cobalt layer 107 is deposited at a temperature of about 400 to 500° C. when PVD is used to improve morphology.

Referring now to FIG. 3B, a titanium layer 109 is formed on the cobalt layer 107 at a temperature of about 400 to 750° C. using CVD. The titanium layer 109 may function as an ohmic layer. The titanium layer 109 is formed on the cobalt layer 107, which has been formed on the inner walls and the bottom of the contact hole 103 and on the insulating layer 105. The titanium layer 109 may be formed to a thickness of about 5 to 150 Å. Because the titanium layer 109 is formed at a relatively high temperature, cobalt silicide 111 is formed on the bottom of the contact hole 103 when forming the titanium layer 109.

Referring now to FIG. 3C, a titanium nitride layer 113 is formed on the cobalt layer 107 and the titanium layer 109 at a temperature of about 400 to 750° C. using CVD. The titanium nitride layer 113 may be formed to a thickness greater than 50 A, for example, about 50 to 500 Å. The titanium nitride layer 113 may function as a diffusion barrier layer for preventing the diffusion of a material, which will be formed as a plug, for example, tungsten. As a result, the cobalt layer 107, the titanium layer 109, and the titanium nitride layer 113 may operate as a barrier metal layer 115.

Referring now to FIG. 3D, a plug 117 is formed on the barrier metal layer 115 to fill the contact hole 103 to provide a metal contact. The plug 117 may comprise a tungsten (W) layer, a titanium nitride (TiN) layer, an aluminum (Al) layer, a copper (Cu) layer, a molybdenum (Mo) layer, a molybdenum nitride (MoN) layer, and/or a tantalum nitride (TaN) layer.

Unlike a conventional method in which two thermal processes and a strip process are performed, the cobalt silicide may function as an ohmic layer by performing relatively simple processing while forming a metal contact in a semiconductor device in accordance with some embodiments of the present invention described above with respect to FIGS. 3A through 3D. In addition, in accordance with some embodiments of the present invention described above with respect to FIGS. 3A through 3D, the cobalt layer and the titanium layer formed on the bottom of the contact hole may function as an ohmic layer. Accordingly, the thickness of the cobalt layer may be reduced compared to that of conventional methods in which only the cobalt layer is used as an ohmic layer. Furthermore, the cobalt silicide is formed when forming the titanium layer at a relatively high temperature, which may allow the thickness of the cobalt layer to be reduced.

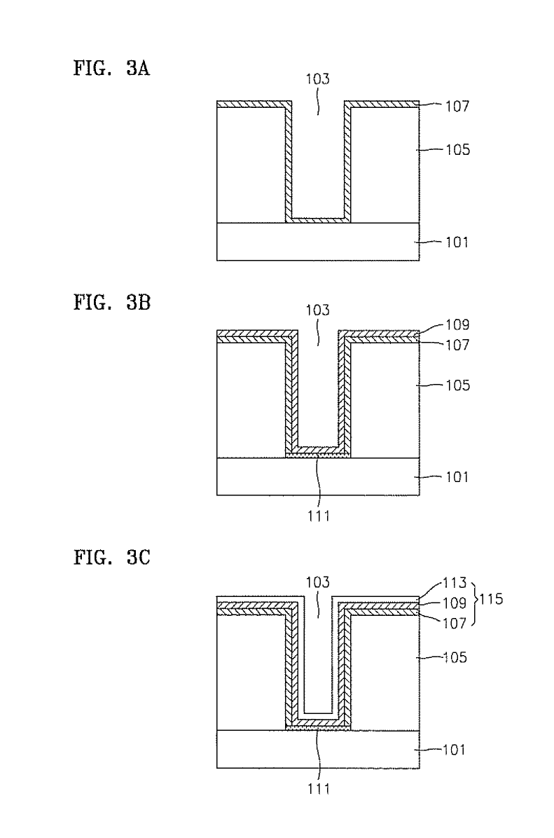

FIG. 4 is a sectional view that illustrates methods for forming a metal contact in a semiconductor device according to additional embodiments of the present invention. The structure and operative effects of the FIG. 4 embodiments of the present invention are similar to those of the embodiments described with respect to FIGS. 3A through 3D. In FIG. 4, however, a plug 119 comprises a titanium nitride layer, which is used as a barrier metal layer. More specifically, a metal contact in a semiconductor device is formed as described above with respect to FIGS. 3A and 3B. Thereafter, referring to FIG. 4, the plug 119 is formed on a titanium layer 109 to fill a contact hole 103 so that a metal contact is completed. The plug 119 may comprise a titanium nitride layer having a thickness of about 20 to 3000 Å.

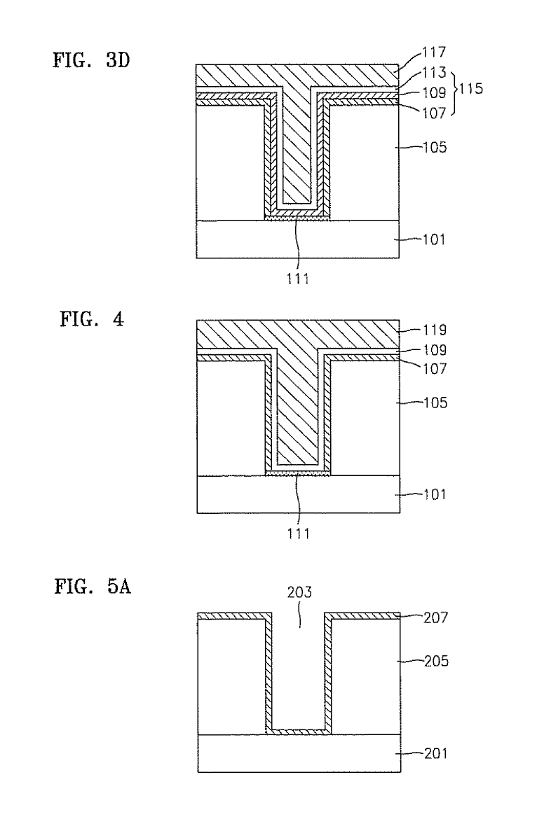

FIGS. 5A through 5C are sectional views that illustrate methods for forming a metal contact in a semiconductor device according to additional embodiments of the present invention. Referring to FIG. 5A, an insulating layer 205 having a contact hole 203 therein is formed on a silicon substrate 201. A cobalt layer 207, which my function as an ohmic layer, is formed on the inner walls and the bottom of the contact hole 203 and on the insulating layer 205. The cobalt layer 207 may be formed to a thickness of about 5 to 200 A. The cobalt layer 207 may be formed using PVD or CVD including ALD. When the cobalt layer 207 is formed using PVD, the cobalt layer 207 may be deposited at a temperature of about 25 to 500° C. In particular embodiments, the cobalt layer 207 is deposited at a temperature of about 400 to 500° C. when PVD is used to improve morphology.

Referring now to FIG. 5B, a titanium nitride layer 209 is formed on the cobalt layer 207 at a temperature of about 400 to 750° C. using CVD. The titanium nitride layer 209 is formed on the cobalt layer 207, which has been formed on the inner walls and the bottom of the contact hole 203 and on the insulating layer 205. The titanium nitride layer 209 may be formed to a thickness greater than 50 Å, for example, about 50 to 150 Å. The titanium nitride layer 209 may function as a diffusion barrier layer for preventing a material, which will be formed as a plug, for example, tungsten, into a lower silicon layer. Because the titanium nitride layer 209 is formed at a relatively high temperature, cobalt silicide 211 is formed on the bottom of the contact hole 203 when forming the titanium nitride layer 209. Accordingly, the cobalt layer 207 and the titanium nitride layer 209 may operate as a barrier metal layer.

Referring now to FIG. 5C, a plug 213 is formed on the titanium nitride layer 209 as the barrier metal layer to fill the contact hole 203 to provide a metal contact. The plug 213 may comprise a tungsten (W) layer, a titanium nitride (TiN) layer, an aluminum (Al) layer, a copper (Cu) layer, a molybdenum (Mo) layer, a molybdenum nitride (MoN) layer, and/or a tantalum nitride (TaN) layer.

Unlike a conventional method in which two thermal processes and a strip process are performed, the cobalt silicide may function as an ohmic layer by performing relatively simple processing while forming a metal contact in a semiconductor device in accordance with some embodiments of the present invention described above with respect to FIGS. 5A through 5C.

In addition, in accordance with some embodiments of the present invention described above with respect to FIGS. 5A through 5C, the cobalt silicide is formed when the titanium layer is formed at a relatively high temperature. Accordingly, the thickness of the cobalt layer maybe reduced.

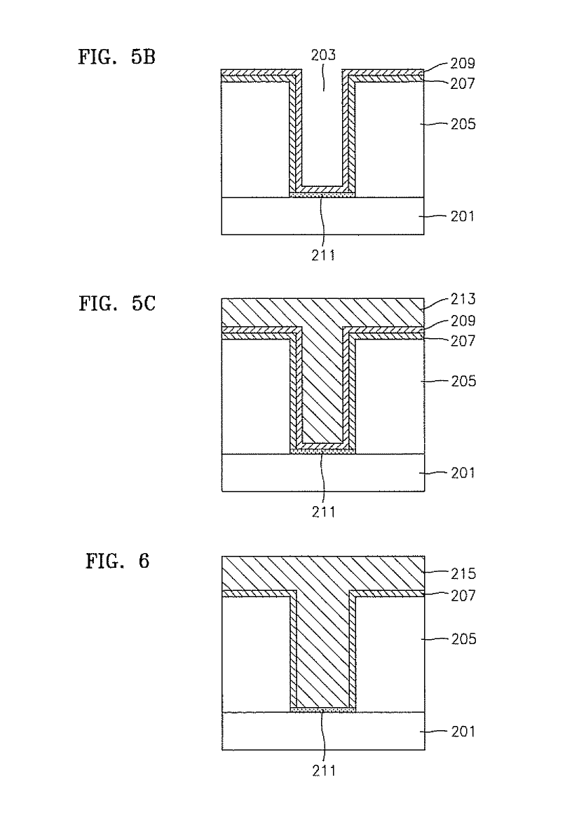

FIG. 6 is a sectional view that illustrates methods for forming a metal contact in a semiconductor device according to additional embodiments of the present invention. The structure and operative effects of the FIG. 6 embodiments of the present invention are similar to those of the embodiments described with respect to FIGS. 5A through 5C. In FIG. 6, however, a plug 215 comprises a titanium nitride layer, which is used as a barrier metal layer. More specifically, a metal contact in a semiconductor device is formed as described above with respect to FIG. 5A. Thereafter, referring now to FIG. 6, the plug 215 is formed on a cobalt layer 217 to fill a contact hole 203. The plug 215 may comprise a titanium nitride layer having a thickness of about 20 to 3000 A. When forming the plug 215, cobalt silicide 211 is formed on the bottom of the contact hole 203.

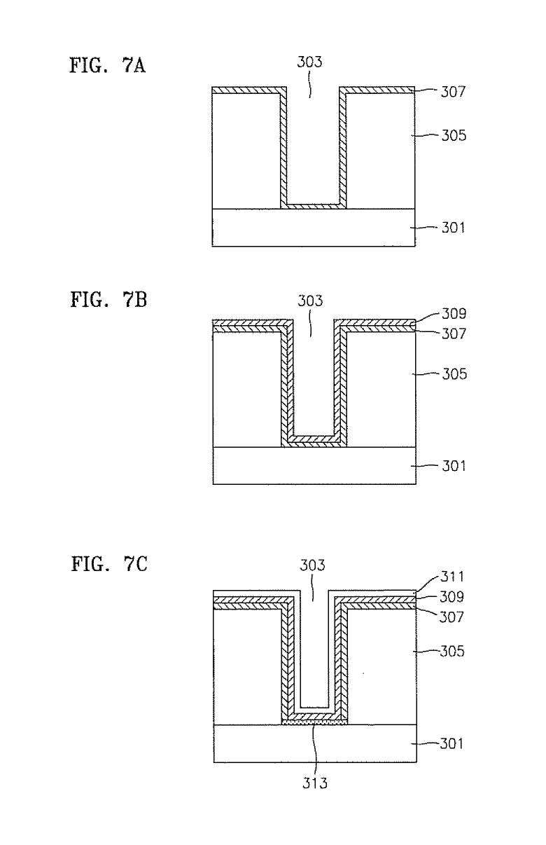

FIGS. 7A through 7D are sectional views that illustrate methods for forming a metal contact in a semiconductor device according to additional embodiments of the present invention. Referring now to FIG. 7A, an insulating layer 305 having a contact hole 303 therein is formed on a silicon substrate 301. A titanium layer 307, which may function as an ohmic layer, is formed on the inner walls and the bottom of the contact hole 303 and on the insulating layer 305. The titanium layer 307 may have a thickness of about 5 to 150 Å. The titanium layer 307 maybe formed using PVD as shown in FIG. 7A. In other embodiments, the titanium layer 307 maybe formed at a temperature of about 400 to 750° C. using CVD. When the titanium layer 307 is formed at a temperature using CVD, titanium silicide is formed on the bottom of the contact hole 303, which is not shown in FIG. 7A.

Referring now to FIG. 7B, a cobalt layer 309, which may function as an ohmic layer, is formed on the titanium layer 307. The cobalt layer 309 may have a thickness of about 5 to 200 Å. The cobalt layer 309 may be formed using PVD or CVD including ALD. When the cobalt layer 309 is formed using PVD, the cobalt layer 309 is deposited at a temperature of about 25 to 500° C. In particular embodiments, the cobalt layer 309 is deposited at a temperature of about 400 to 500° C. when PVD is used to improve morphology.

Referring now to FIG. 7C, a titanium nitride layer 311 is formed on the cobalt layer 309 at a temperature of about 400 to 750° C. using CVD. The titanium nitride layer 311 is formed on the cobalt layer 309, which has been formed on the inner walls and the bottom of the contact hole 303 and on the insulating layer 305. The titanium nitride layer 311 may have a thickness greater than 50 A, for example, about 50 to 500 A. Because the titanium nitride layer 311 is formed at a relatively high temperature, complex silicide 313 of titanium silicide and cobalt silicide is formed on the bottom of the contact hole 303 when forming the titanium nitride layer 311. The complex silicide 313, the titanium layer 307, and the cobalt layer 309 may function as an ohmic layer. The titanium nitride layer 311 may function as a diffusion barrier layer for preventing the diffusion of a material, which will be formed as a plug, for example, tungsten. As a result, the titanium layer 307, the cobalt layer 309, and the titanium nitride layer 311 may function as a barrier metal layer.

Referring now to FIG. 7D, a plug 315 is formed on the titanium nitride layer 311 to fill the contact hole 303 so that a metal contact is completed. The plug 315 may comprise a tungsten (W) layer, a titanium nitride (TiN) layer, an aluminum layer (Al), a copper (Cu) layer, a molybdenum (Mo) layer, a molybdenum nitride (MoN) layer, and/or a tantalum nitride (TaN) layer.

Unlike a conventional method in which two thermal processes and a strip process are performed, the cobalt silicide may function as an ohmic layer by performing relatively simple processing while forming a metal contact in a semiconductor device in accordance with some embodiments of the present invention described above with respect to FIGS. 7A through 7D. In addition, in accordance with some embodiments of the present invention described above with respect to FIGS. 7A through 7D, the cobalt layer and the titanium layer formed on the bottom of the contact hole may function as an ohmic layer. Accordingly, the thickness of the cobalt layer may be reduced compared to that of conventional methods in which only the cobalt layer is used as an ohmic layer. Furthermore, the cobalt silicide is formed when forming the titanium layer at a relatively high temperature, which may allow the thickness of the cobalt layer to be reduced.

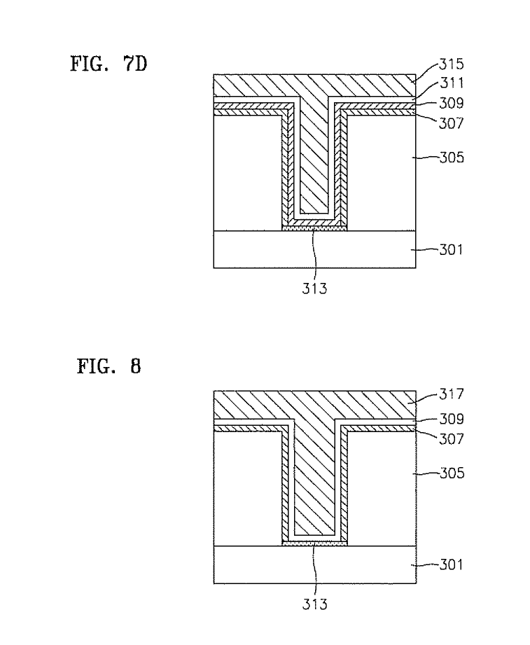

FIG. 8 is a sectional view that illustrates methods for forming a metal contact in a semiconductor device according to additional embodiments of the present invention. The structure and operative effects of the FIG. 8 embodiments of the present invention are similar to those of the embodiments described with respect to FIGS. 7A through 7D. In FIG. 8, however, a plug 317 comprises a titanium nitride layer, which is used as a barrier metal layer. More specifically, a metal contact in a semiconductor device is formed as described above with respect to FIGS. 7A and 7B. Thereafter, referring now to FIG. 8, the plug 317 is formed on a cobalt layer 309 to fill a contact hole 303. The plug 317 may comprise a titanium nitride layer having a thickness of about 20 to 3000 Å. When forming the plug 317, cobalt silicide 313 is formed on the bottom of the contact hole 303.

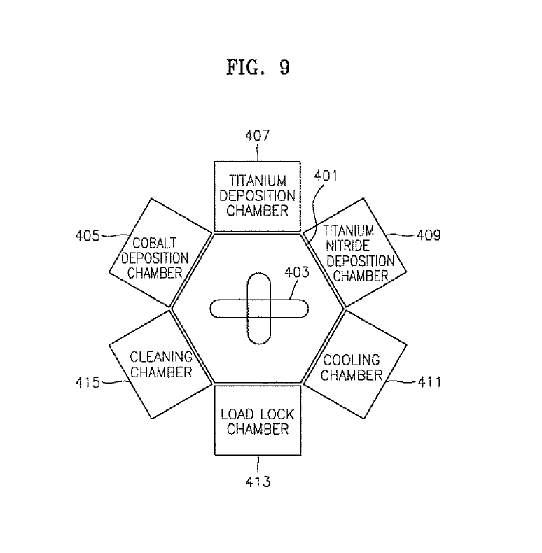

FIG. 9 is a schematic view illustrating manufacturing equipment used for forming a metal contact in a semiconductor device in accordance with some embodiments of the present invention. More specifically, the equipment according to embodiments of the present invention comprises a plurality of chambers installed on a body 401 and a transfer module 403, which is located in the body 401 for transferring wafers to each chamber. The chambers installed on the body 401 include a cobalt deposition chamber 405, a titanium deposition chamber 407, a titanium nitride deposition chamber 409, a cooling chamber 411, a load lock chamber 413, and a cleaning chamber 415. A wafer loaded in the load lock chamber 413 having an insulating layer with a contact hole formed therein formed thereon is cleaned in the cleaning chamber 415 and layers are formed on the wafer as it passes through each of the chambers 405, 407, and 409. Thereafter, the wafer including the layers is cooled in the cooling chamber 411. The cooled wafer is then discharged to the outside via the load lock chamber 413.

According to some embodiments of the present invention, when a metal contact in a semiconductor device is formed using the above-described equipment, the depositions of the cobalt layer, the titanium layer, and the titanium nitride layer, the depositions of the cobalt layer and the titanium nitride layer, and/or the depositions of the titanium layer, the cobalt layer, and the titanium nitride layer can be performed on the wafer in situ after the wafer is cleaned without a vacuum break.

If the cobalt layer is deposited in cobalt layer deposition equipment and a titanium layer and a titanium nitride layer are deposited in the other equipment after a vacuum break as in a conventional method, CoOₓ may be generated on the cobalt layer so that the generation of an ohmic layer is interrupted and a resistance is increased. Accordingly, a cleaning process may be required after the deposition of the cobalt layer. When the equipment of FIG. 9 is used, however, the wafers are cleaned and the cobalt layer, the titanium layer, and the titanium nitride layer are deposited in situ without a vacuum break so that the number and the time of processes are reduced while attaining a relatively stable contact resistance.

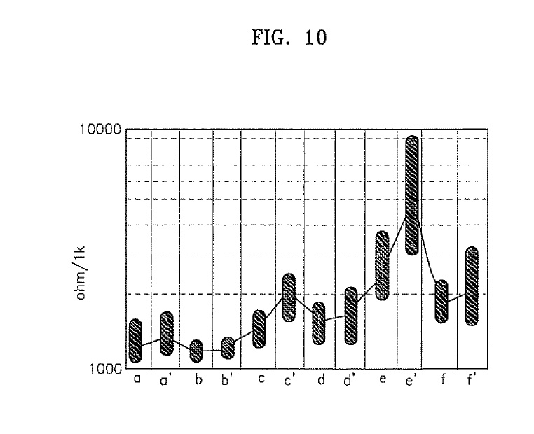

FIG. 10 is a graph that illustrates contact resistances when metal contacts are formed in semiconductor devices according to conventional methods and methods according to various embodiments of the present invention. The horizontal axis denotes experimental conditions and the vertical axis denotes the contact resistance distribution of 1000 contacts. More specifically, reference numerals a and a′ denote contact resistances when a cobalt layer is formed to a thickness of 100 Å, a titanium layer is formed to a thickness of 75 Å using CVD, and a titanium nitride layer is formed to a thickness of 250 Å using CVD according to the embodiments of FIGS. 3A through 3D. Reference numerals b and b′ denote contact resistances when the cobalt layer is formed to a thickness of 200 Å, the titanium layer is formed to a thickness of 75 Å using CVD, and the titanium nitride layer is formed to a thickness of 250 Å using CVD according to the embodiments of FIGS. 3A through 3D. Reference numerals c and c′ denote contact resistances when the cobalt layer is formed to a thickness of 100 Å according to the embodiments of FIGS. 7A through 7D. Reference numerals d and d′ denote contact resistances of conventionally formed cobalt silicide. Reference numerals e, e′, f, and f′ denote contact resistances of conventionally formed titanium silicide. In addition, reference numerals a, b, c, d, e, and f are the contact resistances when the layers are annealed at a temperature of 750° C. for 30 minutes. Reference numerals a′, b′, c′, d′, e′, and f′ are the contact resistances when the layers are annealed at a temperature of 750° C. for 30 minutes twice.

As shown in FIG. 10, the contact resistance of a semiconductor device, according to embodiments of the present invention, is generally less than the contact resistances of conventionally formed titanium silicide and cobalt silicide. In addition, even when the thermal processes are performed twice, the contact resistance of the semiconductor device according to embodiments of the present invention is generally less than the contact resistances of conventionally formed titanium silicide and cobalt silicide.

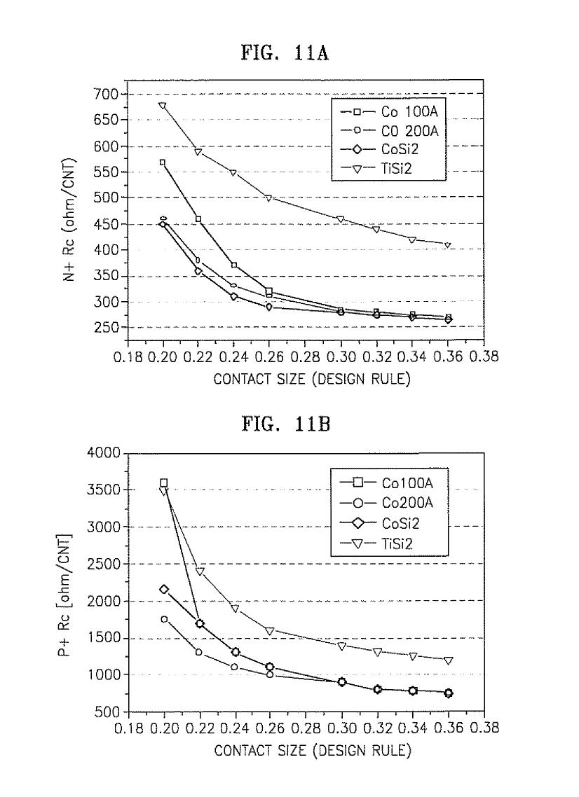

FIGS. 11A and 11B are graphs illustrating contact resistances of N⁺ contacts and P⁺ contacts versus contact size when a bit line contact is formed in prior art semiconductor devices and semiconductor devices according to embodiments of the present invention. More specifically, in FIGS. 11A and 11B, Co 100A, denoted by transparent rectangles, and Co 200A, denoted by transparent circles, are formed by the conditions denoted by reference characters a and b of FIG. 10. In other words, Co 100A and Co 200A denote the cases where metal contacts are formed according to embodiments of the present invention. CoSi2, denoted by transparent diamonds, is formed by the conditions denoted by reference character d of FIG. 10. In other words, CoSi2 denotes the case where a contact is formed by conventional cobalt silicide. TiSi2, denoted by transparent inverse triangles, is formed by the conditions denoted by reference characters e or f of FIG. 10. In other words, TiSi2 denotes the case where a contact is formed using conventionally formed titanium silicide.

As shown in FIGS. 11A and 11B, the contact resistance of the bit line contact, which is formed according to embodiments of the present invention, is less than the contact resistance of the conventional bit line contact where cobalt silicide or titanium silicide is used. In particular, the effect is more significant when the contact size is reduced.

Unlike a conventional method in which two thermal processes and a strip process are performed, the cobalt silicide may function as an ohmic layer by performing relatively simple processing while forming a metal contact in a semiconductor device in accordance with some embodiments of the present invention. In addition, in accordance with some embodiments of the present invention, the cobalt layer and the titanium layer formed on the bottom of the contact hole may function as an ohmic layer. Accordingly, the thickness of the cobalt layer may be reduced compared to that of conventional methods in which only the cobalt layer is used as an ohmic layer. Furthermore, the cobalt silicide is formed when forming the titanium layer at a relatively high temperature, which may allow the thickness of the cobalt layer to be reduced.

Examples in which the embodiments of forming a metal contact are used in a semiconductor device will now be described. Embodiments of the present invention described above can be used in devices that include, but are not limited to, a semiconductor device (e.g., a dynamic random access memory (DRAM) device, a flash memory device that is a non-volatile memory device, and a phase change random access memory (PRAM) device).

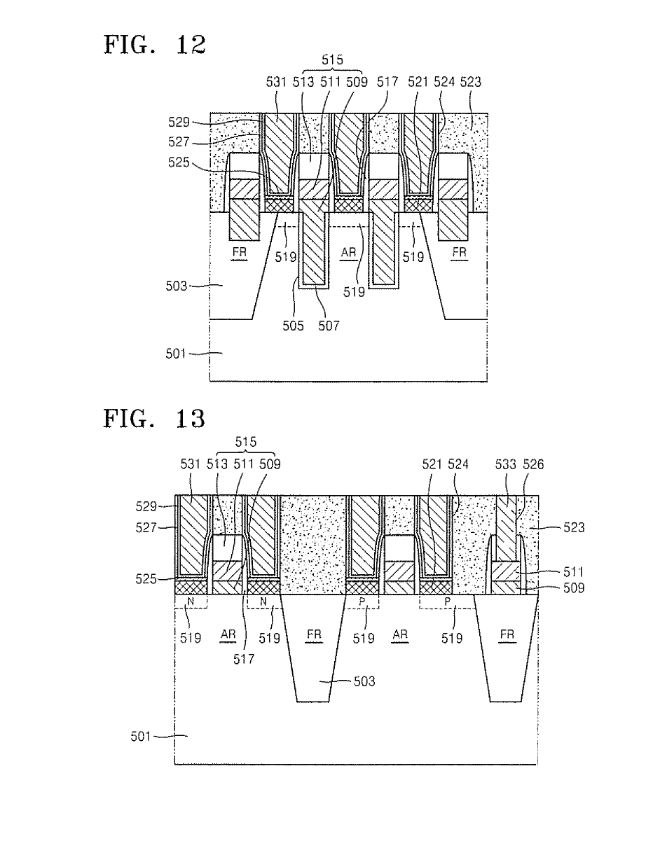

FIGS. 12 and 13 are cross-sectional views illustrating a cell array region and a peripheral circuit region, respectively, of a DRAM device manufactured using a method according to some embodiments of the present invention.

In particular, FIGS. 12 and 13 illustrate a structure that includes a recess channel array transistor that is an example of the DRAM device. Because a channel is formed along a circumference surface of a recess channel trench 505 in the recess channel array transistor, the length of the channel can be long, and the occurrence of a punchthrough phenomenon between a source region and a drain region can be reduced or minimized.

More particularly, a trench field region (FR) 503 is formed on a semiconductor substrate 501 (e.g., a silicon substrate), which defines an active region AR. The recess channel trench 505 is formed in the semiconductor substrate 501 of the cell array region illustrated in FIG. 12. A gate oxide layer 507 is formed on an inner wall of the recess channel trench 505. A gate stack 515, in which a gate polysilicon layer 509, a gate metal layer 511, and a capping layer 513 are sequentially formed, is formed on the gate oxide layer 507 to fill he recess channel trench 505. The gate metal layer 511 may comprise tungsten (W), tungsten silicide (WSix), cobalt (Co), cobalt silicide (CoSix), copper (Cu), and/or aluminum (Al). The gate stack 515 is formed on an active region of the peripheral circuit region illustrated in FIG. 13. However, a gate oxide, which may be formed on the semiconductor substrate 501, is not shown in FIG. 13 for convenience.

A spacer 517 is formed on either wall of the gate stack 515. A source/drain region 519 is formed on a semiconductor substrate 510 of a lower part of either wall of the gate stack 515. In the peripheral circuit region, the impurities of the source/drain region 519 may be differently configured in an N type or a P type device. A raised source/drain region 521 is disposed on the source/drain region 519. The raised source/drain region 521 is formed in a structure in which a silicon epitaxial layer is formed on the semiconductor substrate 501, which is doped with impurities. When the raised source/drain region 521 is included, because the length of the channel can be long, the occurrence of the punchthrough phenomenon between the source region and the drain region can be reduced or minimized.

An inter-insulating layer 523 is formed on the semiconductor substrate 501, wherein the inter-insulating layer 523 includes a first contact hole 524 that insulates the gate stack 515 and exposes the raised source/drain region 521. The first contact hole 524 is formed by etching the inter-insulating layer 523 using the spacer 517. When the first contact hole 524 is formed, a second contact hole 526 exposing the gate metal layer 511 of the peripheral circuit region is also formed.

A cobalt silicide 525 (or complex silicide) layer and a plug 531 are formed in the first contact hole 524 using the methods illustrated in FIGS. 3A through 3D, 4, 6, 7A through 7D or 8 to complete a metal contact. Because the raised source/drain region 521 including the silicon source is formed on the bottom of the first contact hole 524, the cobalt silicide 525 (or complex silicide) layer can be formed.

In FIGS. 12 and 13, a reference number 525 is the same layer (element) as that of each of reference numbers 111, 211 and 313. A reference number 527 is the same layer (element) as that of each of reference numbers 107, 109, 207, 307 and 309, which represents a metal layer or silicide (i.e. cobalt layer, titanium layer or a complex layer thereof (or double layer thereof)). A reference number 529 is the same layer (element) as that of each of reference numbers 113, 209 and 311, which represents a barrier metal layer. A reference number 531 is the same layer (element) as that of each of reference numbers 117, 119, 213, 215, 315 and 317, which represents a plug layer. Although a barrier metal layer 529 and the plug 531 are both illustrated in FIGS. 12 and 13, a plug may be formed as a barrier metal layer, according to embodiments of the present invention described above.

Although a plug 533 is illustrated to be formed in the second contact hole 526, when the gate metal layer 511 is formed of tungsten silicide including the silicon source, or the second contact hole 526 is formed on a gate polysilicon layer, the same metal contact as the first contact hole 524 may be formed in the second contact hole 526.

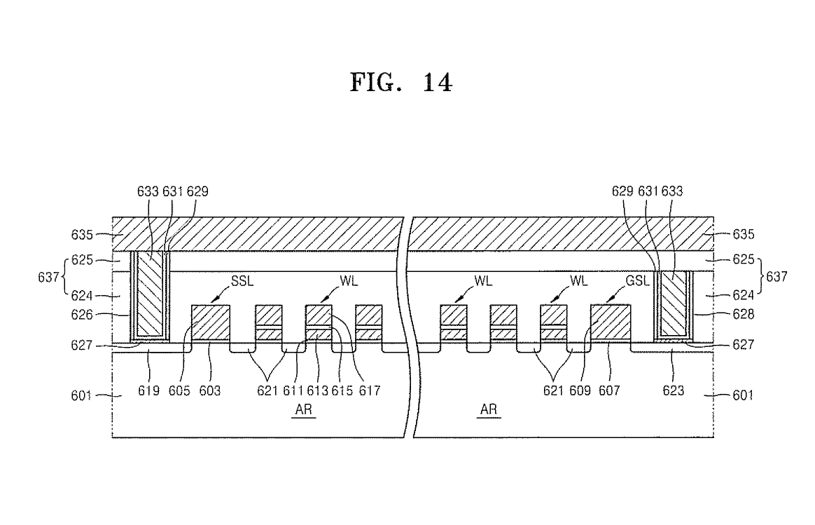

FIGS. 14 and 15 are cross-sectional views illustrating a cell array region of a flash memory device manufactured using a method according to some embodiments of the present invention.

In particular, a trench field region (FR) 602 is formed on a semiconductor substrate 601 (e.g., a silicon substrate), which defines an active region AR. Referring to FIG. 14, a string selection line SSL, a ground selection line GSL, and a word line WL are formed on the semiconductor substrate 601 of the active region.

The string selection line SSL includes a gate insulating layer 603 and a string selection gate line 605 that are sequentially stacked. The ground selection line GSL includes a gate insulating layer 607 and a ground selection gate line 609 that are sequentially stacked. The string selection gate line 605 and the ground selection gate line 609 may comprise polysilicon, tungsten (W), tungsten silicide (WSix), cobalt (Co), cobalt silicide (CoSix), copper (Cu), and/or aluminum (Al).

The word line WL includes a tunnel insulating layer 611, an electric charge storage pattern 613, a blocking insulating pattern 615, and a control gate line 617 that are sequentially stacked. The electric charge storage pattern 613 may be formed of doped polysilicon or undoped polysilicon. In other embodiments, the electric charge storage pattern 613 may be formed of a material layer having deep level traps (e.g., nitride silicon or nano crystal particle). The blocking insulating pattern 615 may be formed of an oxide layer or an oxide-nitride-oxide (ONO) layer. In other embodiments, the blocking insulating pattern 615 may be formed of a high dielectric layer having a higher dielectric constant than the tunnel insulating layer 611 (e.g., an insulating metal oxide such as hafnium oxide (HfO) or aluminum oxide (Al₂O₃)). The control gate line 617 and the ground selection line GSL may comprise polysilicon, tungsten (W), tungsten silicide (WSix), cobalt (Co), cobalt silicide (CoSix), copper (Cu), and/or aluminum (Al).

A cell source/drain region 621 is formed on an active region of either side of the word line WL. A common drain region 619 is formed on an active region of one side of the string selection line SSL. A common source region 623 is formed on an active region of one side of the ground selection line GSL. The string selection line SSL, a plurality of word lines WL, cell source/drain regions 621, and ground selection line GSL are arranged between the common drain region 619 and the common source region 623.

An inter-insulating layer 637, 624 or 625, which insulates the string selection line SSL, the ground selection line GSL, and the word line WL includes a first contact hole 626 and a second contact hole 628, which respectively expose the common drain region 619 and the common source region 623. Referring to FIG. 15, an inter-insulating layer 637 including the first contact hole 626 exposing the active region of the semiconductor substrate 601 is formed.

A cobalt silicide layer 627 (or complex silicide) and a plug 633 are formed in the first contact hole 626 and the second contact hole 628 using the methods illustrated in FIGS. 3A through 3D, 4, 5A through 5C, 6, 7A through 7D or 8 to complete a metal contact. Because each bottom of the first contact hole 626 and the second contact hole 628 is a silicon layer or silicon substrate, the cobalt silicide 627 (or complex silicide) can be formed.

In FIGS. 14 and 15, a reference number 627 is the same layer (element) as that of each of reference numbers 111, 211 and 313. A reference number 629 is the same layer (element) as that of each of reference numbers 107, 109, 207, 307 and 309, which represents a metal layer or silicide (i.e. cobalt layer, titanium layer or a complex layer thereof (or double layer thereof)). A reference number 631 is the same layer (element) as that of each of reference numbers 113, 209 and 311, which represents a barrier metal layer. A reference number 633 is the same layer (element) as that of each of reference numbers 117, 119, 213, 215, 315 and 317, which represents a plug layer. Although a barrier metal layer 631 and the plug 633 are both illustrated in FIGS. 14 and 15, a plug may be formed as barrier metal layer, according to embodiments of the present invention described above. A bit line 635 is formed on the plug 633, wherein a second barrier metal layer 639 is interposed between the plug 633 and the bit line 645. The bit line 635 may comprise tungsten (W), copper (Cu), aluminum (Al), nitride titanium (TiN), nitride tantalum (TaN), molybdenum (Mo) and/or nitride molybdenum (MoN).

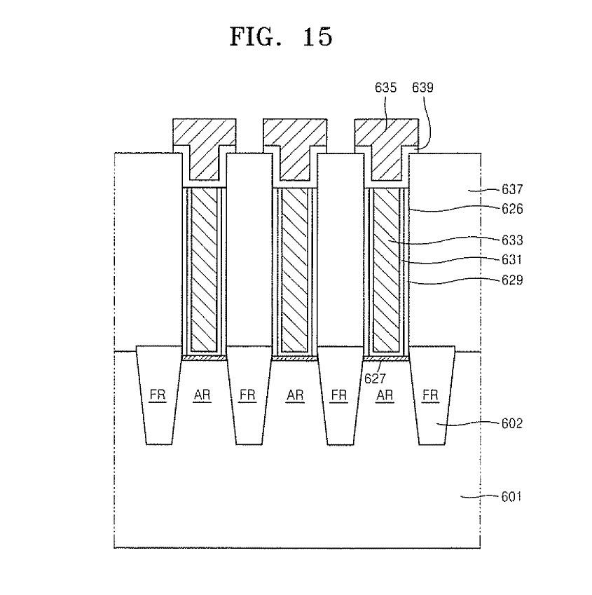

FIGS. 16 and 17 are cross-sectional views illustrating a peripheral circuit region of a flash memory device manufactured using a method according to some embodiments of the present invention.

In particular, the same reference numerals in FIGS. 16 and 17 denote the same elements in FIGS. 14 and 15. Various type transistors are formed on the peripheral circuit region. A gate stack includes a gate insulating layer 641, a gate poly silicon layer 643, a gate metal layer 645, and a cap layer 647, which are sequentially stacked and is formed on the peripheral circuit region. The gate metal layer 645 may comprise tungsten (W), tungsten silicide (WSix), cobalt (Co), cobalt silicide (CoSix), copper (Cu), and/or aluminum (Al).

An inter-insulating layer 652 is formed, which insulates the gate stack and includes a first contact hole 653 and a second contact hole 655 exposing the semiconductor substrate 601 and the gate metal layer 645. An impurity region may be formed on the semiconductor substrate 601 at the bottom of the first contact hole 653 and the second contact hole 655. A cobalt silicide layer 627 (or complex silicide) and a plug 633 are formed in the first contact hole 653 and the second contact hole 655 using the methods illustrated in FIGS. 14 and 15 to complete a metal contact. Because each bottom of the first contact hole 653 and the second contact hole 655 is a silicon layer including a silicon source and a tungsten silicide layer, the cobalt silicide layer 627 (or complex silicide) can be formed.

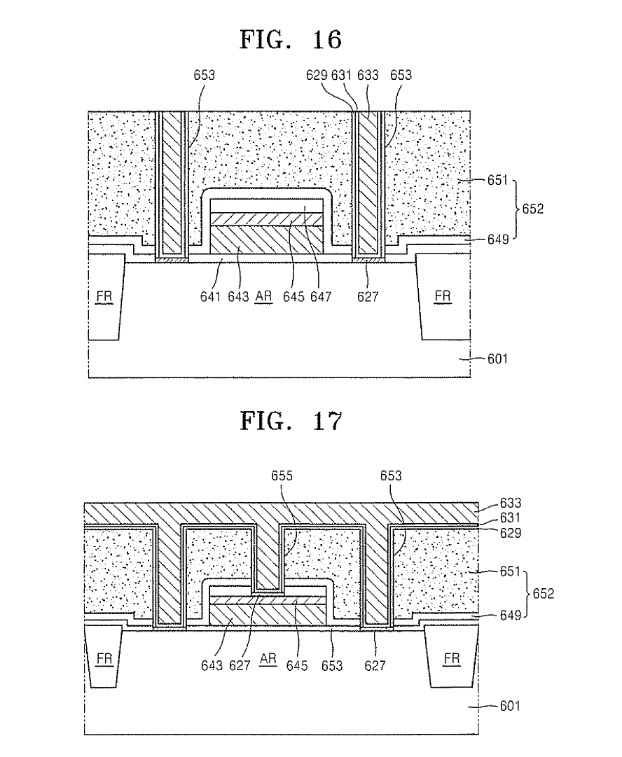

FIG. 18 is a cross-sectional view illustrating a PRAM device manufactured using a method according to some embodiments of the present invention.

In particular, FIG. 18 illustrates a PRAM device including a diode. A first insulating layer 703 is formed on a semiconductor substrate 701 (e.g., a silicon substrate). Word lines WL1-WLn are formed in the first insulating layer 703. A second insulating layer 708 including a contact hole 707 exposing the word lines WL1-WLn is formed on the word lines WL1-WLn and the first insulating layer 703. The diode including an N-type semiconductor pattern 709 and a P-type semiconductor pattern 711, and the pad layer 713 are sequentially formed in the contact hole 707. The pad layer 713 includes a silicon layer doped with impurities. The pad layer 713 functions as a diode electrode in a phase change memory cell. A spacer 710 is formed on either wall of the contact hole 707 of the pad layer 713.

A cobalt silicide layer 715 (or complex silicide) and a plug 721 are formed in the contact hole 707 including the spacer 710 formed therein using the methods illustrated in FIGS. 3A through 3D, 4, 5A through 5C, 6, 7A through 7D or 8 to complete a metal contact. The plug 721 functions as a lower electrode in the PRAM device. Because the bottom of the contact hole 707 is a silicon layer including silicon source, the cobalt silicide layer 715 (or complex silicide) can be formed.

In FIG. 18, a reference number 715 is the same layer (element) as that of each of reference numbers 111, 211 and 313. A reference number 717 is the same layer (element) as that of each of reference numbers 107, 109, 207, 307 and 309, which represents a metal layer or silicide (i.e. cobalt layer, titanium layer or a complex layer thereof (or double layer thereof)). A reference number 719 is the same layer (element) as that of each of reference numbers 113, 209 and 311, which represents a barrier metal layer. A reference number 721 is the same layer (element) as that of each of reference numbers 117, 119, 213, 215, 315 and 317, which represents a plug layer. Although a barrier metal layer 719 and the plug 721 are both illustrated in FIG. 18, a plug may be formed as a barrier metal layer, according embodiments of the present invention described above.

A phase change layer 723 and an upper electrode 725 are formed on the plug 721. The phase change layer 723 may be a GST layer (GeSbTe layer). The upper electrode 725 is insulated by a third insulating layer 727. A bit line 729 is formed on the upper electrode 725 to configure the PRAM device. The bit line 729 may comprise tungsten (W), copper (Cu), aluminum (Al), nitride titanium (TiN), nitride tantalum (TaN), molybdenum (Mo) and/or nitride molybdenum (MoN).

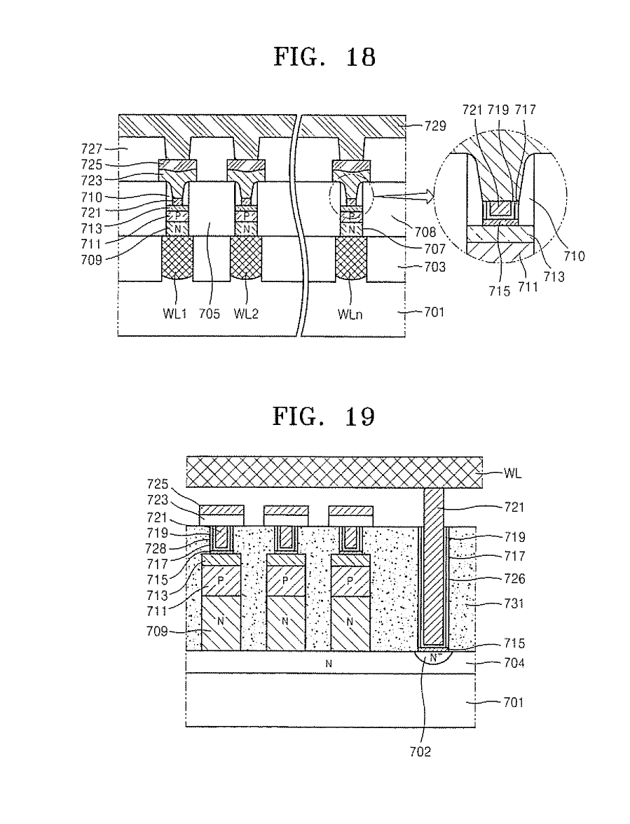

FIG. 19 is a cross-sectional view illustrating a PRAM device manufactured using a method according to further embodiments of the present invention.

In particular, FIG. 19 illustrates a PRAM device including a diode similar to FIG. 18. The same reference numbers in FIG. 19 denote the same elements in FIG. 18. An N-type impurity layer 704 is formed on a semiconductor substrate 701 (e.g., a p-type silicon substrate). An N⁺ impurity layer 702 is partially formed in the N-type impurity layer 704. An inter-insulating layer 731 including a first contact hole 726 and a second contact hole 728, which respectively expose the N⁺ impurity layer 702 and the pad layer 715, is formed on the semiconductor substrate 701.

A cobalt silicide layer 715 (or complex silicide) and a plug 721 are formed in the first contact hole 726 and the second contact hole 728 using the methods illustrated in FIG. 18 to complete a metal contact. Because each bottom of the first contact hole 726 and the second contact hole 728 is a silicon layer including a silicon source, the cobalt silicide layer 715 (or complex silicide) can be formed. The plug 721 is connected to the word line (W/L) in an upper part of the plug 721, which is different from FIG. 18.

In concluding the detailed description, it should be noted that many variations and modifications can be made to the preferred embodiments without substantially departing from the principles of the present invention. All such variations and modifications are intended to be included herein within the scope of the present invention, as set forth in the following claims.

That which is claimed:

1. A method of forming a metal contact in a semiconductor device, comprising:
forming an insulating layer having a contact hole therein on a silicon layer;
forming a cobalt layer on a bottom and inner walls of the contact hole;
forming a cobalt silicide layer at the bottom of the contact hole while forming a titanium layer on the cobalt layer; and
forming a plug on the titanium layer so as to fill the contact hole.

2. The method of claim 1, wherein the plug comprises titanium nitride.

3. The method of claim 1, further comprising:
forming a titanium nitride layer on the titanium layer; and
wherein forming the plug comprises:
forming the plug on the titanium nitride layer so as to fill the contact hole.

4. The method of claim 3, wherein the titanium nitride layer has a thickness of about 50 to 500 Å.

5. The method of claim 4, wherein the titanium nitride layer is formed using chemical vapor deposition (CVD) at a temperature of about 400 to 750° C.

6. The method of claim 3, wherein the plug comprises tungsten (W), titanium nitride (TiN), aluminum (Al), copper (Cu), molybdenum (Mo), molybdenum nitride (MoN), and/or tantalum nitride (TaN).

7. The method of claim 3, wherein the cobalt layer, the titanium layer, and the titanium nitride layer are formed in situ without a vacuum break.

8. The method of claim 1, wherein the cobalt layer has a thickness of about 5 to 200 Å.

9. The method of claim 1, wherein the cobalt layer is formed using one of physical vapor deposition (PVD) and chemical vapor deposition (CVD).

10. The method of claim 9, wherein the cobalt layer is formed using PVD at a temperature of about 25 to 500° C.

11. The method of claim 1, wherein the titanium layer has a thickness of about 5 to 150 Å.

12. The method of claim 1, wherein the titanium layer is formed using chemical vapor deposition (CVD) at a temperature of about 400 to 750° C.

13. The method of claim 1, wherein substrate and insulating layer are cleaned after forming the insulating layer.

14. A method of forming a metal contact in a semiconductor device, comprising:
forming an insulating layer having a contact hole therein on a silicon layer;
forming a titanium layer on a bottom and inner walls of the contact hole;
forming a cobalt layer on the titanium layer;
forming a complex silicide layer comprising titanium silicide and cobalt silicide at the bottom of the contact hole while forming a titanium nitride layer on the cobalt layer; and
forming a plug on the titanium nitride layer so as to fill the contact hole.

15. A method of forming a metal contact in a semiconductor device, comprising:
forming an insulating layer having a contact hole therein on a silicon layer;
forming a titanium layer on a bottom and inner walls of the contact hole;
forming a cobalt layer on the titanium layer; and
forming a complex silicide layer comprising titanium silicide and cobalt silicide at the bottom of the contact hole while forming a plug that fills the contact hole on the cobalt layer.
